(19) United States
(12) Patent Application Publication
(10) Pub. No.: US 2025/0076422 A1
(43) Pub. Date: Mar. 6, 2025

(54) METHOD, SYSTEM, AND COMPUTER PROGRAM PRODUCT UTILIZING SPATIALLY-RESOLVED B1 AMPLITUDE-BASED TUNING OF MAGNETIC RESONANCE IMAGES

(71) Applicant: CANON MEDICAL SYSTEMS CORPORATION, Otawara-shi (JP)

(72) Inventor: Andrew James WHEATON, Vernon Hills, IL (US)

(73) Assignee: CANON MEDICAL SYSTEMS CORPORATION, Otawara-shi (JP)

(21) Appl. No.: 18/461,683

(22) Filed: Sep. 6, 2023

(51) Int. Cl. G01R 33/24; G01R 33/36

(52) U.S. Cl. CPC G01R 33/246; G01R 33/3607; G01R 33/3628; G01R 33/0017

(57) ABSTRACT

A method, system and computer program product for performing imagine processing including obtaining spatially-resolved B1 amplitude measurements obtained using at least one RF parameter; performing at least one spatially-resolved analysis on the obtained spatially-resolved B1 amplitude measurements; determining an updated value of the at least one RF parameter to be used in a series of MRI sequences based on the performed spatially-resolved analysis; and storing the updated value of the at least one RF parameter. The updated value of the at least one RF parameter can then be used to perform the series of MRI sequences.

### BACKGROUND OF THE INVENTION

### Field of the Invention

This disclosure relates to a method, system, and computer program product for obtaining a series of magnetic resonance imaging (MRI) images, and, in one embodiment, to a method, system, and computer product for obtaining MRI images by performing spatially-resolved B1 amplitude-based tuning of a series of MRI sequences in a single MRI examination.

### Discussion of the Background

When using MRI systems to perform imaging on a patient, a patient enters the gantry of an MRI system and is subjected to an examination including a series of scan sequences (shown in FIG. 1 as scan sequence to scan sequencen). Having finished the series of scan sequences in the patient exam, a patient exits the MRI system.

Known MRI systems perform an optional per-patient calibration to determine a reference RF transmitter gain level (RFL) prior to beginning an examination as shown in the optional pre-scan sequence 102 of FIG. 1. The RFL is calculated during a pre-scan process across the entirety of at least one slice of a set of 2D slices, thereby computing an RFL representative of the average of voxels within the slice. The reference RFL value subsequently is used to calculate the transmitter gain values to achieve the intended B1 amplitude for all subsequent RF pulses in the MR scan sequences. As would be appreciated by those skilled in the art, the B1 amplitude of the RF pulses has a direct relationship with the flip angle of the RF pulse, and the flip angle of the RF pulse is a primary determinant of MR signal intensity and image contrast. Thus, the RFL value has a known, and direct relationship, to B1 field and flip angle. By measuring the B1 field, the RFL can be directly and simply calculated. In general, if RFL is too low, there will be ‘undertipping’ which is a condition in which the data obtained is obtained when the flip angle is below expectation. By contrast, if RFL is too high, there will be ‘overtipping’ which is a condition in which the data obtained is obtained when the flip angle is above expectation. Both undertipping and overtipping can result in reduced image quality in the resulting MRI images (e.g., dark spots in an image).

However, even within an MRI image, B1 inhomogeneity (AB1) can result in image signal inhomogeneity. When the transmitter magnetic field is non-uniform, non-uniform flip angles and non-uniform signal variations can occur. This effect is pronounced at higher field strengths (e.g., 3T or higher) where B1 variation is greater due to dielectric effects. Variations in effective B1 levels result in darker or lighter regions in images as compared with regions of the image that had the target B1 level. In a conventional spin echo or fast spin echo image, the expected flip angle of the excitation pulse is π/2 and the expected flip angle of the refocusing pulse is x. For this example, darker regions in the image are caused by both undertipping or overtipping where the flip angles are less than or greater than the expected flip angles, respectively. Because the image signal in a conventional spin echo or fast spin echo is roughly proportional to sin³((π/2)*(1+ΔB1)), an exemplary undertipping of −30% results in an inner term of (1+ΔB1=1−0.3=0.7) and a signal=sin³(0.7/2)=0.71, and an exemplary overtipping of +20% results in an inner term of (1+ΔB1=1+0.2=1.2) and a signal=sin³(1.2π/2)=0.86. In the example of field echo imaging, the signal has a more complex relationship with flip angle and tissue T1 relaxation. Therefore, in field echo imaging, both darker (less signal) and lighter (more signal) regions may be produced due to flip angle variation caused by AB1.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

A more complete understanding of this disclosure is provided by reference to the following detailed description when considered in connection with the accompanying drawings, wherein:

FIG. 1 illustrates a patient examination including an optional pre-scan and a series of scan sequences;

FIG. 2 illustrates a schematic block diagram of an MRI system according to an exemplary implementation of the present disclosure;

FIG. 3 illustrates a flowchart showing exemplary processing steps for performing spatially-resolved B1 amplitude-based tuning of MRI images;

FIG. 4A is a color representation of spatially-resolved B1 amplitude data obtained when determining B1 amplitude distributions that would occur when imaging a pair of human thighs at an initial RF transmitter gain level (RFL) acting as an initial RF parameter;

FIG. 4B is an MRI image of the pair of thighs of FIG. 4A when imaged at the initial RFL;

FIGS. 4C-4H are MRI images of the pair of thighs of FIGS. 4A and 4B when imaged at progressively higher RFLs than the initial RFL of FIG. 4B;

FIG. 41 is a greyscale version of the spatially-resolved B1 amplitude data of FIG. 4A;

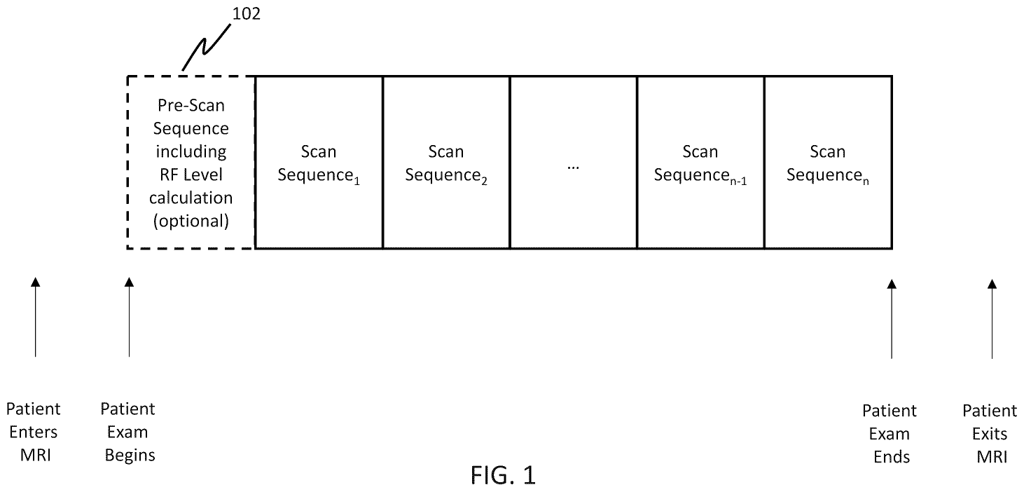

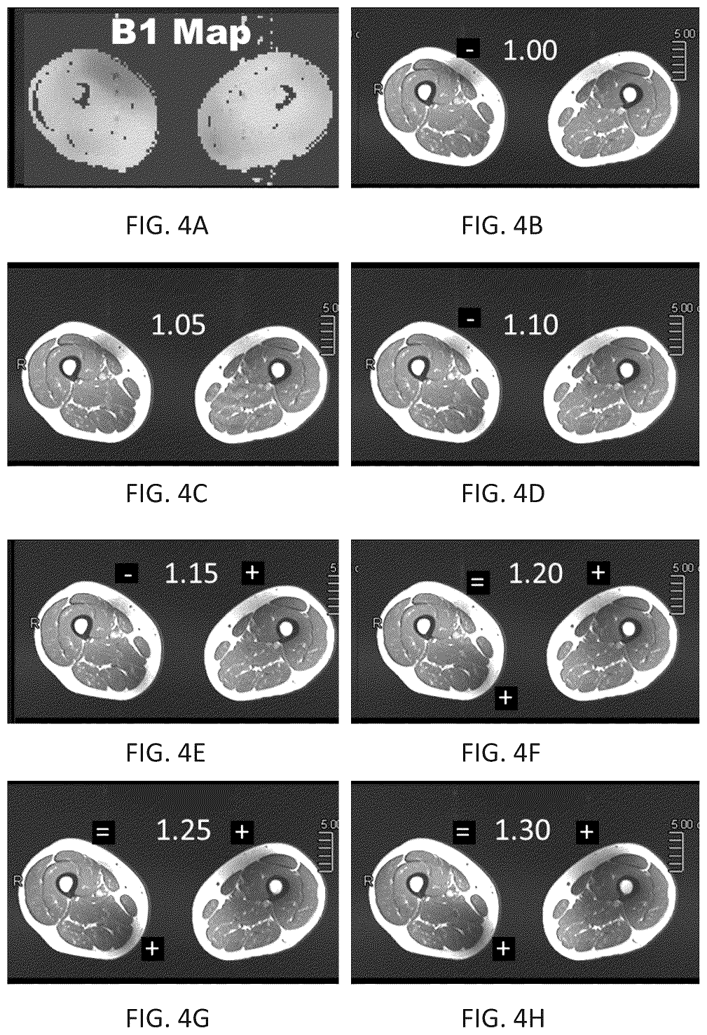

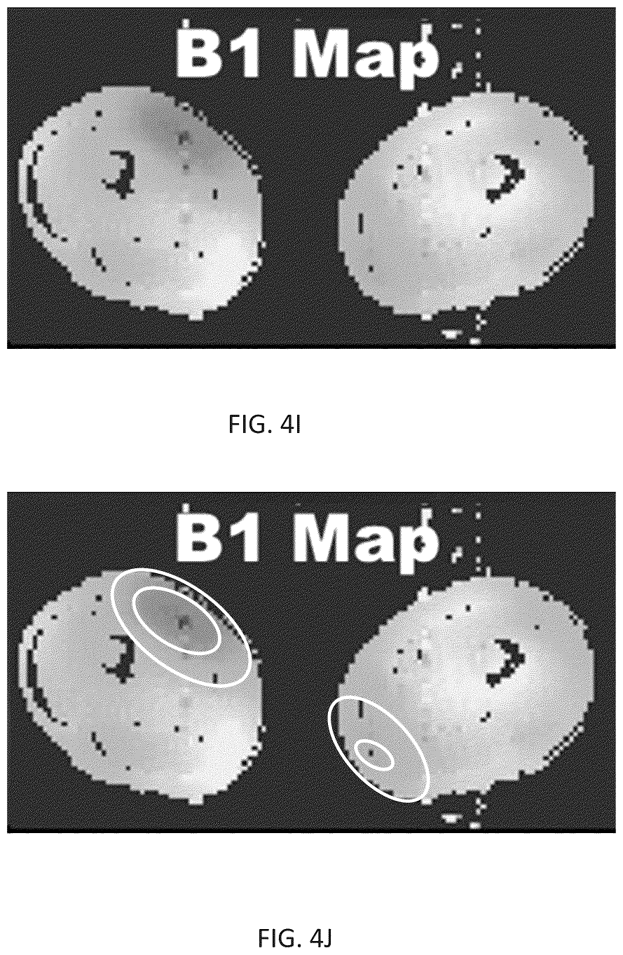

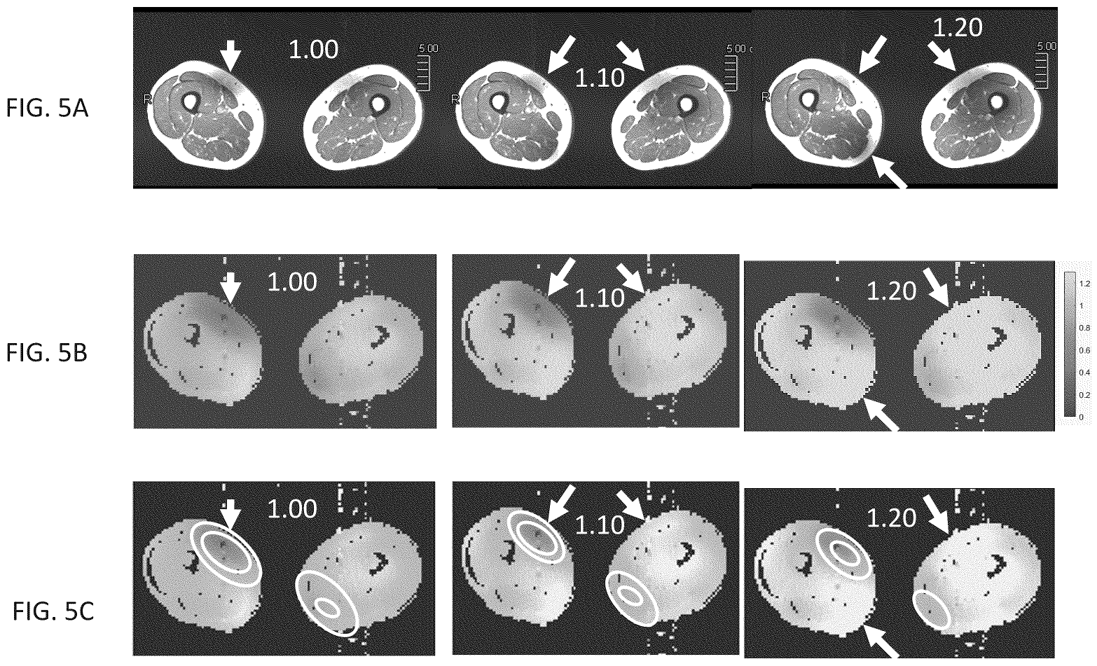

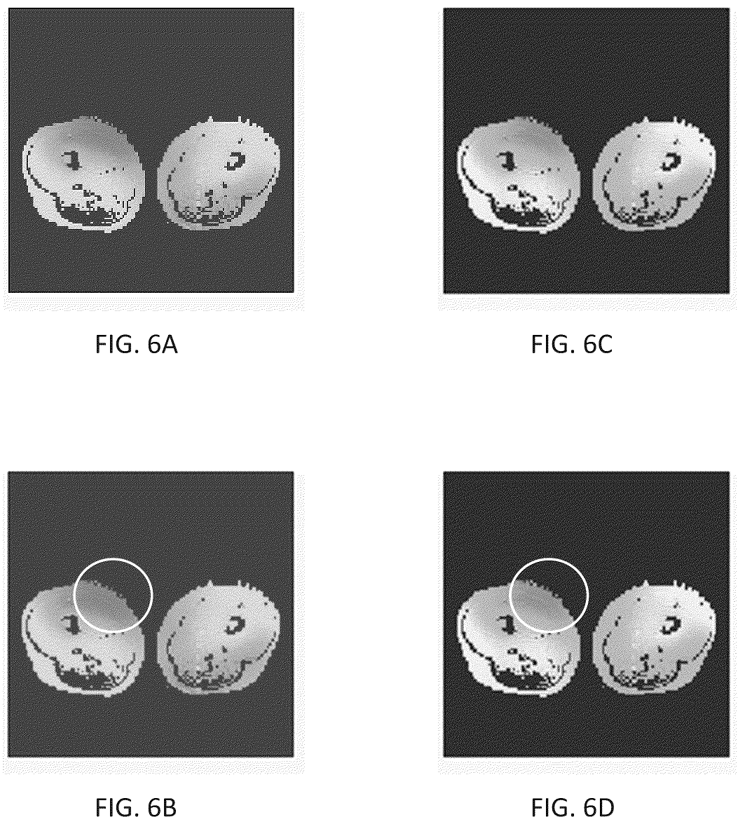

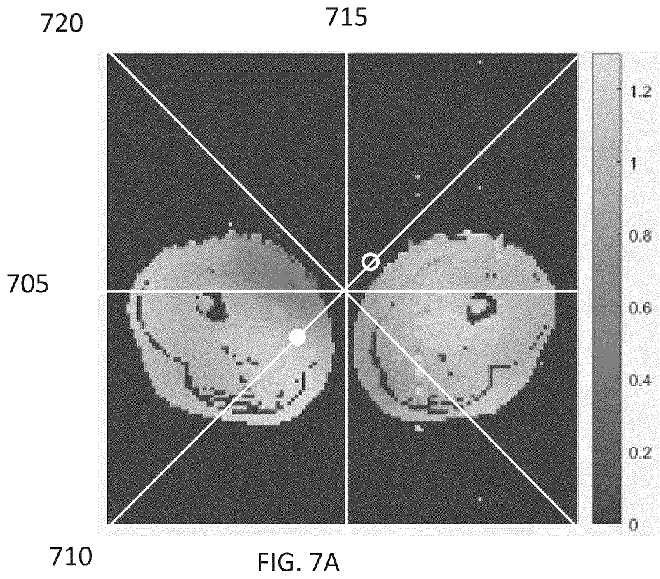

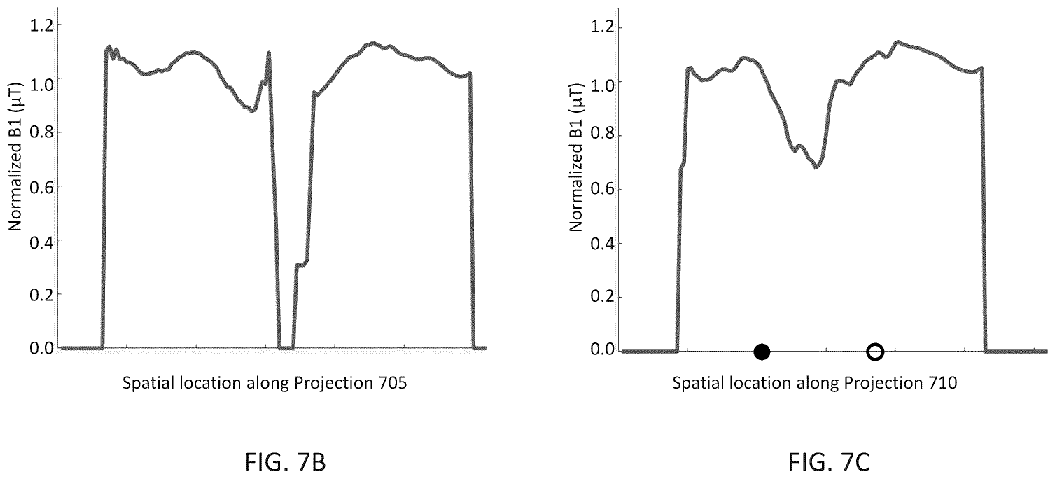

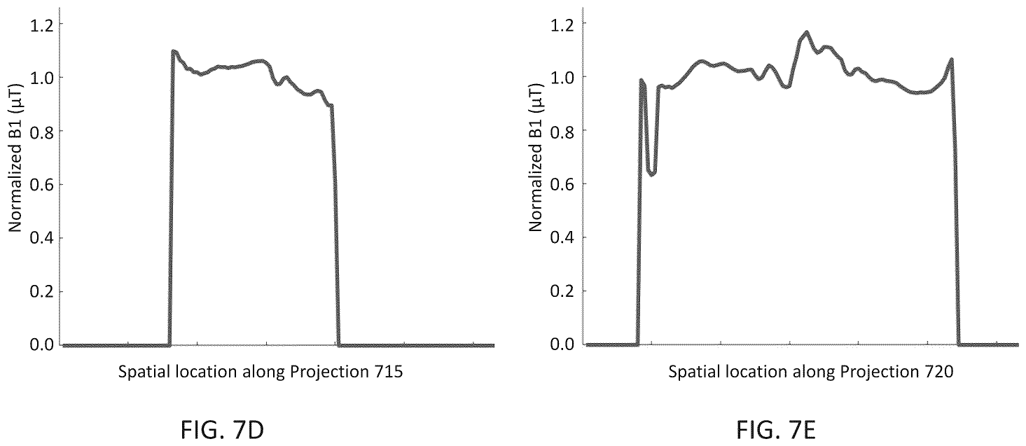

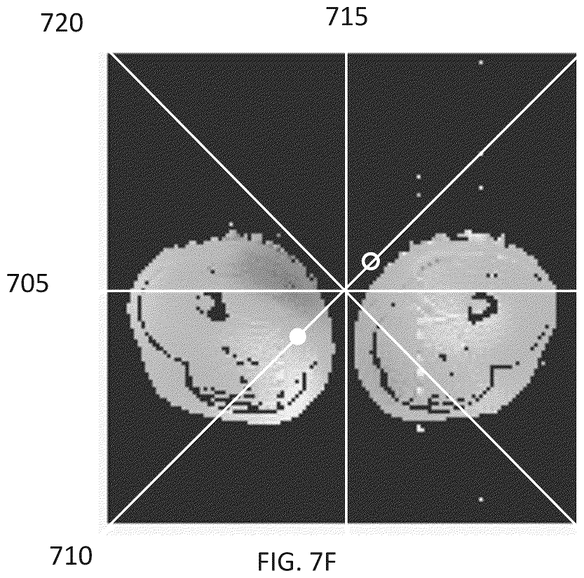

FIG. 4J is an annotated version of the greyscale representation of the spatially-resolved B1 amplitude data of FIG. 4I showing two dark areas representing B1 amplitude data below the intended average value;

FIG. 5A is a series of annotated images obtained by using initial and increased RFLs showing the effects of the RFL on undertipping and overtipping;

FIG. 5B is a series of annotated color B1 amplitude maps obtained at the initial and increased RFLs of FIG. 5A showing how B1 amplitude data changes with changing RFL;

FIG. 5C is a greyscale version of the annotated B1 amplitude maps of FIG. 5B;

FIG. 6A is a color spatially-resolved B1 amplitude map showing variations in B1 amplitude across a portion of an object to be imaged;

FIG. 6B is an annotated version of the color spatially-resolved B1 amplitude map of FIG. 6A showing a selected circular region of interest to be used to determine an amount of correction to be applied to an initial RF imaging parameter;

FIG. 6C is a greyscale version of the spatially-resolved B1 amplitude map of FIG. 6A;

FIG. 6D is an annotated greyscale version of the color spatially-resolved B1 amplitude map of FIG. 6A showing a selected circular region of interest to be used to determine an amount of correction to be applied to an initial RF imaging parameter;

FIG. 7A is an exemplary color B1 amplitude map of a subject's thighs;

FIG. 7B is a B1 amplitude projection corresponding to a projection orientation displayed by line 705 of FIG. 7A;

FIG. 7C is a B1 amplitude projection corresponding to a projection orientation displayed by line 710 of FIG. 7A;

FIG. 7D is a B1 amplitude projection corresponding to a projection orientation displayed by line 715 of FIG. 7A;

FIG. 7E is a B1 amplitude projection corresponding to a projection orientation displayed by line 720 of FIG. 7A; and

FIG. 7F is an exemplary greyscale B1 map of FIG. 7A.

### DETAILED DESCRIPTION

Exemplary embodiments are illustrated in the referenced figures of the drawings. It is intended that the embodiments and figures disclosed herein are to be considered illustrative rather than restrictive. No limitation on the scope of the technology and of the claims that follow is to be imputed to the examples shown in the drawings and discussed herein.

The embodiments are mainly described in terms of particular processes, systems and computer program products provided in particular implementations. However, the processes, systems, and computer program products will operate effectively in other implementations. Phrases such as ‘an embodiment’, ‘one embodiment’, and ‘another embodiment’ can refer to the same or different embodiments. The embodiments will be described with respect to methods and compositions having certain components. However, the methods and compositions can include more or less components than those shown, and variations in the arrangement and type of the components can be made without departing from the scope of the present disclosure.

The exemplary embodiments are described in the context of methods having certain steps. However, the methods and compositions operate effectively with additional steps and steps in different orders that are not inconsistent with the exemplary embodiments. Thus, the present disclosure is not intended to be limited to the embodiments shown but is to be accorded the widest scope consistent with the principles and features described herein and as limited only by the appended claims.

Furthermore, where a range of values is provided, it is to be understood that each intervening value between an upper and lower limit of the range—and any other stated or intervening value in that stated range—is encompassed within the disclosure. Where the stated range includes upper and lower limits, ranges excluding either of those limits are also included. Unless expressly stated, the terms used herein are intended to have the plain and ordinary meaning as understood by those of ordinary skill in the art. Any definitions are intended to aid the reader in understanding the present disclosure, but are not intended to vary or otherwise limit the meaning of such terms unless specifically indicated.

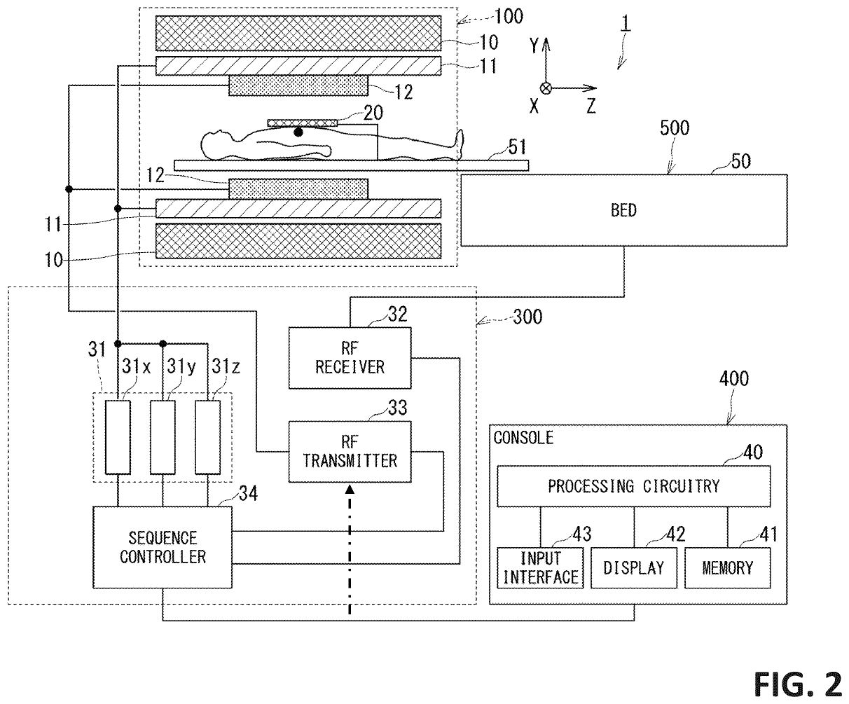

Referring now to the drawings, wherein like reference numerals designate identical or corresponding parts throughout the several views, FIG. 2 is a block diagram illustrating an overall configuration of an MRI apparatus 1 according to the first embodiment. The MRI apparatus 1 of the first embodiment includes a gantry 100, a control cabinet 300, a console 400, and a bed 500.

The gantry 100 includes a static magnetic field magnet 10, a gradient coil assembly 11, and a whole body (WB) coil 12, and these components are housed in a cylindrical housing. The bed 500 includes a bed body 50 and a table 51. In addition, the MRI apparatus 1 includes at least one RF coil 20 to be disposed close to an object.

The control cabinet 300 includes three gradient coil power supplies 31 (31 x for an X-axis, 31 y for a Y-axis, and 31 z for a Z-axis), an RF receiver 32, an RF transmitter 33, and a sequence controller 34.

The static magnetic field magnet 10 of the gantry 100 is substantially in the form of a cylinder, and generates a static magnetic field inside a bore, which is a space formed inside the cylindrical structure and serves as an imaging region of the object (for example, a patient). The static magnetic field magnet 10 includes a superconducting coil inside, and the superconducting coil is cooled down to an extremely low temperature by liquid helium. The static magnetic field magnet 10 generates a static magnetic field by supplying the superconducting coil with an electric current to be provided from a static magnetic field power supply (not shown) in an excitation mode. Afterward, the static magnetic field magnet 10 shifts to a permanent current mode, and the static magnetic field power supply is separated. Once it enters the permanent current mode, the static magnetic field magnet 10 continues to generate a strong static magnetic field for a long time, for example, over one year. Note that the static magnetic field magnet 10 may be configured as a permanent magnet.

The gradient coil assembly 11 is also substantially in the form of a cylinder and is fixed to the inside of the static magnetic field magnet 10. The gradient coil assembly 11 has a three-channel structure and includes an X-axis gradient coil 11 x, a Y-axis gradient coil 11 y, and a Z-axis gradient coil 11 z (not shown individually). The X-axis gradient coil 11 x is supplied with electric current from the gradient magnetic field power supply 31 x so as to generate a gradient magnetic field Gx in the X-axis direction. The Y-axis gradient coil 11 y is supplied with electric current from the gradient magnetic field power supply 31 y so as to generate a gradient magnetic field Gy in the Y-axis direction. The Z-axis gradient coil 11 z is supplied with electric current from the gradient magnetic field power supply 31 z so as to generate a gradient magnetic field Gz in the Z-axis direction.

The bed body 50 of the bed 500 can move the table 51 in the vertical direction and in the horizontal direction. The bed body 50 moves the table 51 with an object placed thereon to a predetermined height before imaging. Afterward, when the object is imaged, the bed body 50 moves the table 51 in the horizontal direction so as to move the object to the inside of the bore.

The WB body coil 12 is shaped substantially in the form of a cylinder so as to surround the object, and is fixed to the inside of the gradient coil assembly 11. The WB coil 12 applies RF pulses to be transmitted from the RF transmitter 33 to the object, and receives magnetic resonance (MR) signals emitted from the object due to excitation of hydrogen nuclei.

The RF coil 20 receives MR signals emitted from the object at a position close to the object. The RF coil 20 includes plural coil elements, for example. Depending on the anatomical imaging part of the object, there are various RF coils 20 such as for the head, for the chest, for the spine, for the lower limbs, and for the whole body. Of these various RF coils, FIG. 2 illustrates the RF coil 20 for imaging the chest.

The RF transmitter 33 transmits an RF pulse to the WB coil 12 on the basis of an instruction from the sequence controller 34. The RF receiver 32 detects MR signals received by the WB coil 12 and/or the RF coil 20, and transmits raw data obtained by digitizing the detected MR signals to the sequence controller 34.

The sequence controller 34 performs a scan of the object by driving the gradient coil power supplies 31, the RF transmitter 33, and the RF receiver 32 under the control of the console 400. When the sequence controller 34 receives the raw data from the RF receiver 32 by performing the scan, the sequence controller 34 transmits the received raw data to the console 400.

The sequence controller 34 includes processing circuitry (not shown). This processing circuitry is configured as, for example, a processor for executing predetermined programs or configured as hardware such as a field programmable gate array (FPGA) and an application specific integrated circuit (ASIC).

The console 400 is configured as a computer that includes processing circuitry 40, a memory 41, a display 42, and an input interface 43.

The memory 41 is a recording medium including a read-only memory (ROM) and a random access memory (RAM) in addition to an external memory device such as a hard disk drive (HDD) and an optical disc device. The memory 41 stores various programs to be executed by a processor of the processing circuitry 40 as well as various data and information.

The display 42 is a display device such as a liquid crystal display panel, a plasma display panel, and an organic EL panel.

The input interface 43 includes various devices for an operator to input various data and information, and is configured of, for example, a mouse, a keyboard, a trackball, and/or a touch panel.

The processing circuitry 40 is, for example, a circuit provided with a central processing unit (CPU) and/or a special-purpose or general-purpose processor. The processor implements various functions described below by executing the programs stored in the memory 41. The processing circuitry 40 may be configured of hardware such as an FPGA and an ASIC. The various functions described below can also be implemented by such hardware. Additionally, the processing circuitry 40 can implement the various functions by combining hardware processing and software processing based on its processor and programs.

The console 400 controls the entirety of the MRI apparatus 1 with these components. Specifically, the console 400 accepts imaging conditions such as the type of pulse sequence, various information, and an instruction to start imaging to be inputted by a user such as a medical imaging technologist through the input interface 43 including a mouse and a keyboard. The processing circuitry 40 causes the sequence controller 34 to perform a scan on the basis of the inputted imaging conditions and reconstructs an image on the basis of the raw data transmitted from the sequence controller 34, i.e., digitized MR signals. The reconstructed image is displayed on the display 42 and is stored in the memory 41.

In the configuration of the MRI apparatus 1 shown in FIG. 2, the control cabinet 300, the gantry 100, and the bed 500 (i.e., all the components except the console 400) constitute an imaging unit or scanner.

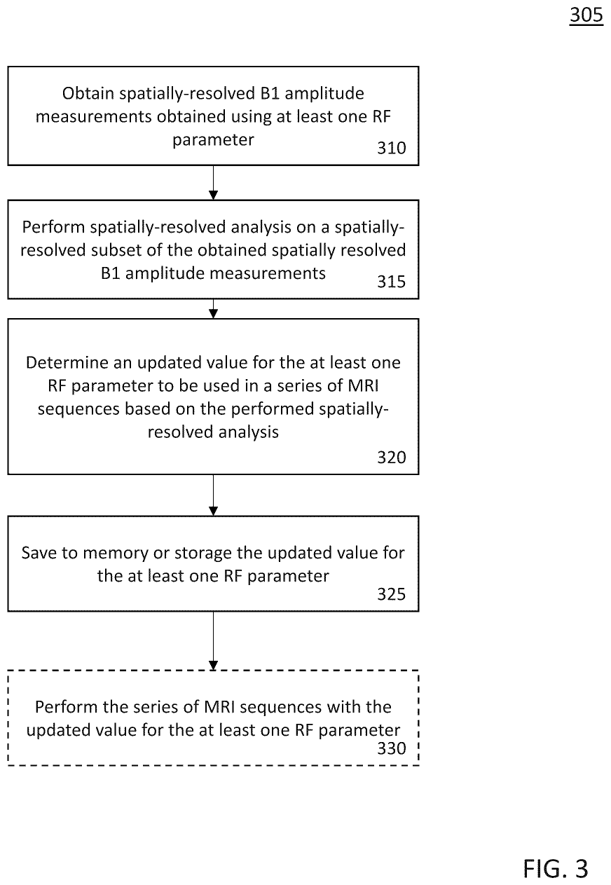

FIG. 3 illustrates a flowchart showing an exemplary method 305 including exemplary processing steps for performing spatially-resolved B1 amplitude-based tuning of MRI images to be obtained by an MRI apparatus 1. Method 305 begins with step 310, and, in step 310, the MRI apparatus 1 (or a remote system communicating with and working in conjunction with the MRI apparatus 1) obtains spatially-resolved B1 amplitude measurements of an object (e.g., a person to be imaged) using an initial RF parameter (e.g., at an initial RFL) set in accordance with a set of MRI sequences to be obtained of the object. Exemplary processes for obtaining spatially-resolved B1 amplitude data include, but are not limited to, performing Bloch-Siegert Shift (BSS) processing, Actual Flip angle Imaging (AFI), Dual Refocusing Echo Acquisition Mode (DREAM), Double Angle Method (DAM) processing, Phase-sensitive (PS) processing, and Saturation recovery (SR) processing. The obtained spatially-resolved B1 amplitude measurements may be obtained as a 1D projection, a 2D slice, and a 3D volume, and subsets of the measurements may be used rather than complete sets of measurements.

As used herein, “obtain” is intended to mean receive from a memory 41 or storage system of the MRI system 1 or receive from an external source in its entirety. “Obtain” is also intended to mean that a portion of the information is obtained from one source and then augmented with additional information or modified such that the combined/modified information is then accessible to the MRI system 1 (e.g., stored in the memory 41 or in a storage system of the MRI system 1). For example, the series of MRI sequences may be obtained from one source (memory 41 or an external device) and then augmented with additional information such as spatially-resolved B1 amplitude measurement sequences. Likewise, the series of MRI sequences may be obtained from one source (memory 41 or an external device) and then modified to change the at least one initial RF imaging parameter.

FIG. 4A is a color representation of spatially-resolved B1 amplitude data obtained (e.g., using BSS or AFI methods of B1 mapping) when determining B1 amplitude distributions that would occur when imaging a pair of human thighs at an initial RFL (i.e., the RFL such that the average B1 value across a region being imaged is expected to be 1.0). As illustrated, a complete B1 amplitude map is obtained that corresponds to a particular cross-section of the object (e.g., person) to be imaged, although less than a complete B1 amplitude map for the cross-section also may be obtained. The B1 amplitude data may be obtained during a portion of a pre-scan that performs B1 shim calibration and, therefore, does not extend the processing time of the MRI process as a whole. Alternatively, if B1 shim calibration is not used, then a fast projection may be used and may require only a short scan time (e.g., approximately 60-80 ms). In yet another embodiment, the B1 amplitude data may be obtained after a portion of a pre-scan that performs B1 shim calibration so that the B1 amplitude data is as consistent as possible prior to obtaining the spatially-resolved B1 amplitude measurements. In alternate embodiments, complete or partial B1 amplitude maps also may be obtained for additional cross-sections.

FIG. 4B is an MRI image of the pair of thighs of FIG. 4A when imaged at the initial RFL. FIG. 4B includes an annotation ‘-’ on the top right portion of the thigh shown on the lefthand side (“the left thigh”) to accentuate a shadow on the left thigh. The shadow corresponds to the blue and green portions of the B1 map of FIG. 4A indicating that the B1 amplitude data is not the B1 target value of 1.0 (shown in yellow in FIG. 4A) but a value less than the B1 target value that causes signal distortion due to undertipping. The green portions correspond to approximately 80% of the target B1, and the blue portions correspond to about 60% of the target B1 with the amplitude values decreasing towards the center of the blue portion and increasing going away from the center of the blue portion. The blue and green portions of FIG. 4A correspond to the darker portions of the greyscale B1 amplitude map of FIG. 4I. Those regions are highlighted in the annotated B1 amplitude map of FIG. 4J where the outer white ovals correspond to the green regions having B1 values of approximately 80% of the target B1, and the inner white ovals correspond to the blue regions having B1 values of approximately 60% of the target B1. In FIG. 4J, the amplitude values decrease towards the center of the inner oval and increase going away from the center of the inner oval.

FIGS. 4C-4H are MRI images of the pair of thighs of FIGS. 4A and 4B when imaged at progressively higher RFLs than the initial RFL (i.e., at 1.05, 1.10, 1.15, 1.20, 1.25, and 1.30 times higher than the initial RFL). As can be seen in FIG. 4C, when imaged at an RFL 1.05 times that of FIG. 4B (i.e., 1.05×), the portion of the image that has signal distorted by undertipping in FIG. 4B is improved (i.e., has less of a shadow) as compared with FIG. 4B, but a shadow still remains. As RFL increases to 1.10× and 1.15×, the effect of undertipping continues to decrease until about 1.20× where the shadow begins to disappear in FIG. 4F (as noted by the annotation ‘=’). However, the increase in RFL brings with it an overtipping in the thigh on the right starting at least at RFL1.15× (in FIG. 4E) and with it worsening of other portions of the image (as noted by the annotation ‘+’). Even greater RFLs show at least two regions with overtipping in FIGS. 4G and 4H (also denoted by ‘+’).

Returning to the explanation of the method 305 of FIG. 3, having obtained the spatially-resolved B1 amplitude measurements in step 310, control passes to step 315 where a spatially-resolved analysis is performed on a spatially-resolved subset of the obtained spatially-resolved B1 amplitude data in order (e.g., to address at least one of undertipping and overtipping issues that result from using the initial RFL of the obtained series of MRI sequences). In one embodiment, the received spatially-resolved B1 amplitude measurements are quantized, optionally filtered, and then subjected to histogram processing. For example, obtained B1 amplitude data is quantized into different values that are used to calculate the histogram.

Prior to calculating the histogram, the B1 amplitude data may be subjected to filtering. For example, values below a particular threshold may be discarded as corresponding to air as opposed to tissue that is the portion that is of interest to the image reviewer (e.g., a medical professional such as a radiologist). Similarly, values that are beyond a statistical threshold amount (e.g., four standard deviations) from the average value of the values may be discarded as being likely anomalous data. Furthermore, a location-based mask may be applied to the data such that any of the values from outside the mask area are discarded. The mask area may be obtained via input from the operator of the MRI apparatus or may be selected automatically by the apparatus based on factors, stored in memory 41, such as the type of region being imaged (e.g., thigh, prostate, skull), and/or patient-specific parameters (e.g., a weight of a patient that may affect the side/location of the region being imaged with respect to a center of an imaging area). Alternatively, the B1 amplitude data may be filtered and then quantized.

The number of occurrences of quantized data values across the set of B1 amplitude values being processed are then determined from the histogram, and processing based on the calculated information can be performed in step 320. As will be discussed in greater detail below, the set of B1 amplitude values being processed may be from at least one 1D projection, from a partial or a complete slice (i.e., two-dimensional data), or from a partial or complete three-dimensional volume.

In a first embodiment of step 320, spatially-resolved processing is performed to address at least one set of extreme values in the B1 amplitude data. For example, the lowest X % (e.g., 10% or 15%) of the B1 amplitude data is used to increase the average B1 value that will be produced during imaging. (As used herein, “X” is considered as a first “extreme” threshold percentage.) In one such embodiment, the transmitter RFL that would result in an average B1 value of a predetermined target amount (B1_{target}) (e.g., 1.0) that was obtained in step 310 is modified by dividing the B1_{target} value by the average value of the lowest X % of the B1 amplitude values of the histogram (where that average is referred to as “B1_{low region}”). Accordingly, the new transmitter RFL (RFL_{new}) that would be used instead of the initial RFL (RFLᵢₙᵢₜᵢₐₗ) producing, on average, the B1_{target} value is calculated as:

$$R F {L}_{n e w} = R F {L}_{initial} * ( B {1}_{t a r g e t} ) / ( B {1}_{low region} ) . \qquad ( Eq . l )$$

Such a modification would raise B1 in the dark hole regions, but some regions may end up being overtipped as a result.

In an alternate embodiment, to avoid overtipping, the B1_{target} value is initially reduced by a reduction factor (RFx) (e.g., 0.85) so that very low B1 values in regions of low B1 values do not unduly modify the resulting image quality. In one such embodiment, the new transmitter RFL would be calculated as:

$$R F {L}_{n e w} = R F {L}_{initial} * ( RFx * B {1}_{t a r g e t} ) / ( B {1}_{low region} ) . \qquad ( Eq . 2 )$$

In yet another embodiment, the value of the new RFL is limited by a predetermined maximum percentage (maxfactor) using, for example, a maximum function (max (x,y)), where the result is no greater than “x”. One such embodiment is described by Equation (3) below.

$$R F {L}_{n e w} = max ( {RFL}_{initial} * maxfactor , {RFL}_{initial} * ( B {1}_{t a r g e t} ) / ( B {1}_{low region} ) ) . \qquad ( Eq . 3 )$$

In yet another embodiment, rather than using the lower extreme values to increase the new RFL value to address undertipping, the higher extreme values (e.g., the highest Y %, such as 10% or 15%) can be used to lower the RFL_{new} to address overtipping by using the corresponding average value (B1_{high region}) instead of B1low region average and/or by using a minimum function instead of a maximum function. (As used herein, “Y” is considered as a second “extreme” threshold percentage.)

While the above embodiments raise or lower the value of RFL_{new} used in the imaging sequence, those embodiments do so by addressing only the average of one of the two extremes. In yet another embodiment of the modification of step 320, a balanced approach is used to account for both the averages of the extreme high and low values in the B1 amplitude data. (The threshold values X and Y for the high and low values, respectively, need not be the same. For example, the high region threshold may be 5% and the low region threshold may be 10%.) In one such embodiment, the method determines a B1_{average} value that is the average of the high and low averages of B_{low region} and B_{high region} according to:

$$B {1}_{average} = ( B {1}_{low region} + B {1}_{high region} ) / 2. \qquad ( Eq . 4 )$$

RFL_{new} is then calculated according to

$$R F {L}_{n e w} = R F {L}_{initial} * ( B {1}_{t a r g e t} ) / ( B {1}_{a v e r a g e} ) . \qquad ( Eq . 5 )$$

Such an embodiment has the advantage of avoiding too much overtipping, although it will generally not raise B1 in low regions as much.

FIG. 5A is a series of annotated images obtained by using initial and increased transmitter RFLs using the above-described techniques of equations (1) and (5) (using all values in the B1 amplitude map that were not filtered out as corresponding to air (i.e., that are larger than the threshold for air)). The image in FIG. 5A (labeled 1.0) using the initial RFL shows a dark shadow region pointed to by the arrow that corresponds with lower than target B1 amplitude values (e.g., lower than 1.0) in the initial B1 map of FIG. 5B (also labeled 1.0). FIG. 5B shows that, at the initial RFL, there is at least one region on each leg that is below the target B1 amplitude. The green portions correspond to approximately 80% of the target B1, and the blue portions correspond to about 60% of the target B1 with the amplitude values decreasing towards the center of the blue portion and increasing going away from the center of the blue portion. The blue and green portions of FIG. 5B correspond to the darker portions of the greyscale B1 amplitude maps of FIG. 5C. Those regions are highlighted in the annotated B1 amplitude maps of FIG. 5C where the outer white ovals correspond to the green regions having B1 values of approximately 80% of the target B1, and the inner white ovals correspond to the blue regions having B1 values of approximately 60% of the target B1. In FIG. 5C, the amplitude values decrease towards the center of the inner oval and increase going away from the center of the blue portion.

Using the B1_{low region} correction technique of Equation (1) described above, the RFL_{new} value was increased to 1.2x in the image labeled 1.2, and the area of the initial shadow is less dark (as indicated by the upper-left arrow in the 1.2 image). The change in RFL corresponds with the increase in B1 value in its corresponding map, and, for example, the B1 values in the leg shown on the left have virtually removed the values in the range of approximately 60% of the target B1. This can be seen in the virtual elimination of the blue region in the right-hand side of the 1.2 B1 amplitude map of FIG. 5B and from the fact that the inner oval has disappeared in the right-hand side of the 1.2 B1 amplitude map of FIG. 5C. However, the technique caused strong exemplary overtipping in the portions identified by the upper-right and lower-left arrows in the image labeled 1.2 and in the portions indicated by the arrows of the corresponding B1 amplitude maps of FIGS. 5B and 5C.

By contrast, using the balanced approach described above with respect to Equation (5), an increase of only 1.10x is used, and the dark anterior hole shadow is improved (but not removed completely) on the left side of the image labeled 1.1 in FIG. 5A. That improvement corresponds to a reduction in green and blue regions of FIG. 5C and in a reduction in the size of the ovals in FIG. 5C. Small overtipping on anterior of the leg shown on the right is observed without undue overtipping.

In each of the above embodiments, having determined (in step 320) at least one updated RF parameter (e.g., a new RFL, a new flip angle, or a new B1 shim setting) to be used in a series of MRI sequences, control passes to step 325. In step 325, the determined at least one updated RF parameter is saved to memory or storage (either by itself or as part of the scan sequences for obtaining series of MRI sequences). In embodiments where steps 310-325 are performed in the MRI apparatus 1, control then passes from step 325 to 330 so that the MRI apparatus can perform the series of MRI sequences (and store their results) before completing the method 305. Alternatively, in embodiments where steps 310-325 are performed outside of the MRI apparatus 1, the MRI apparatus 1 reads the stored at least one updated RF parameter from the memory (e.g., when obtaining the corresponding series of MRI sequences) and performs the series of MRI sequences before completing the method 305.

The spatially-resolved analyses on the received spatially-resolved B1 amplitude data are not limited to the processing described above with respect to steps 315 and 320. In alternate embodiments, the histogram processing is replaced by a number of alternate processing methods described below.

In a first alternate embodiment, the histogram of a full slice is replaced with region of interest processing based on analysis (e.g., visual or automated inspection) of spatially-resolved B1 amplitude data in one-, two-, or three-dimensions. FIG. 6A is a color spatially-resolved B1 amplitude map showing variations in B1 amplitude across a two-dimensional portion of an object to be imaged that can be obtained through the processing of step 310. In an embodiment where an MRI operator is shown the map of FIG. 6A, the MRI operator can, using the input interface 43, select at least one region of interest in the map. FIG. 6B illustrates an exemplary region of interest which the MRI operator has drawn on the B1 amplitude map to indicate the region(s) of interest (i.e., where the system should select the values to use in statistical processing to determine high and/or low regions to use to modify the initial RFL).

FIG. 6C is a greyscale spatially-resolved B1 amplitude map showing variations in B1 amplitude across a two-dimensional portion of an object to be imaged that can be obtained through the processing of step 310 and can be used instead of the color version of FIG. 6A. In an embodiment where an MRI operator is shown the map of FIG. 6C, the MRI operator can, using the input interface 43, select at least one region of interest in the map. FIG. 6D illustrates an exemplary region of interest which the MRI operator has drawn on the B1 amplitude map to indicate the region(s) of interest (i.e., where the system should select the values to use in statistical processing to determine high and/or low regions to use to modify the initial RFL).

FIG. 6B is an annotated version of the color spatially-resolved B1 amplitude map of FIG. 6A showing a circular region of interest drawn or selected by an MRI operator to be used to define the mask of where values are to be selected from to determine an amount of correction to be applied to an initial RF imaging parameter. Shapes other than a circle may be used to specify a two-dimensional region of interest. The shapes, the locations of the shapes, and the size of the shapes may be selected automatically by the apparatus based on factors such as the type of region being imaged (e.g., thigh, prostate, skull), and/or patient-specific parameters (e.g., a weight of a patient that may affect the side/location of the region being imaged with respect to a center of an imaging area). In such a configuration, the two-dimensional region of interest is used like a mask to exclude unwanted data outside of the two-dimensional region of interest.

Alternatively, the MRI apparatus 1 may acquire B1 data in the form of 1D projection data. The geometric orientation of the 1D projection(s) may be selected automatically by the apparatus based on factors such as the type of region being imaged (e.g., thigh, prostate, skull), and/or patient-specific parameters (e.g., a weight of a patient that may affect the side/location of the region being imaged with respect to a center of an imaging area).

In an embodiment using automated inspection, the method utilizes at least one of (1) an artificial neural network trained to produce a correction factor from spatially-resolved B1 amplitude data and (2) a priori empirical knowledge of the expected location(s) of the region(s) of low/high B1 to automatically select a region of interest. For example, based on the region of the object to be scanned, locations of regions of interest having low/high B1 values can be stored in memory 41 along with any factors that may change the locations of the regions of interest (e.g., type of region being imaged and/or patient-specific parameters). For example, due to the physical dielectric effect and roughly cylindrical shape of most patients' legs, the approximate location of low B1 (AB1<1) and high B1 (AB1>1) regions are in approximately the same locations for all humans, and thus the locations of these regions may be known reliably a priori. Small changes in the placement of the regions may be made based on a preceding locator image (e.g. a ‘scout’ image) which is commonly acquired in MR exam to guide the planning of scans in the protocol.

FIGS. 7A to 7E illustrate how the choice of 1D projection orientation can improve the sensitivity of the B1 measurement. The projection data illustrated in FIGS. 7B to 7E correspond to different projection orientations (705, 710, 715, and 720) of the color B1 map in FIG. 7A and of the greyscale B1 map of FIG. 7F. Each of the horizontal axes of FIGS. 7B to 7E corresponds to 128 spatial positions along their respective projection orientations (705, 710, 715, and 720) and, as illustrated, were measured with FOV=45 cm. The projection orientation 710 with B1 projection data illustrated in FIG. 7C is the preferred orientation because it is able to observe the region of low B1 amplitude (e.g., on the anterior left thigh). The dip in the projection data of FIG. 7C between the solid and hollow circles corresponds to the average B1 amplitude values obtained from approximately between the solid and hollow circles of FIGS. 7A and 7F where those average values are obtained orthogonally to the projection orientation.

The other projection orientations (705, 715, and 720 illustrated in FIGS. 7B, 7D, and 7E, respectively) demonstrate how the low and high B1 regions are mostly unobservable due to the averaging of the B1 amplitude along the projected dimension orthogonal to the line. Furthermore, as can be seen from FIGS. 7B-7E, an air threshold may be selected as 0.6 in at least one embodiment.

While the above discussions have been made with respect to performing an analysis on all the (non-air) B1 amplitude values on a particular 1D projection, a sub-portion of any 1D projection may be used instead. For example, a single projection may include plural regions of low B1 values (called “holes”), and statistical calculations which do not distinguish between the plural holes will combine values from the plural holes during processing (e.g., when determining the lowest X % of the non-air values). While some imaging areas may be processed using information from both holes, in an alternate embodiment, only the Z % of lowest values within the hole having the deeper hole are used.

In yet another embodiment, the processing described herein can limit the B1 amplitude data to a particular region in a two-dimensional slice or in three-dimensional volume. For example, the processing can determine a smallest (non-air) value with the dataset as a whole and then select only those values that are within a specified distance (in two or three dimensions) of the lowest value to be used in the calculation of the new RFL. Similarly, a region-growing technique can be used on the two-dimensional slice or three-dimensional volume to determine all the values within a threshold amount that correspond to the hole that has the most low-value data values contiguously connected.

In addition to the other configurations and methods described herein, other configurations and methods are set forth in the not limiting parentheticals set forth below. Those include, but are not limited to:

(1) An image processing method including, but not limited to, obtaining spatially-resolved B1 amplitude measurements obtained using at least one RF parameter; performing at least one spatially-resolved analysis on a spatially-resolved subset of the obtained spatially-resolved B1 amplitude measurements; determining an updated value of the at least one RF parameter to be used in a series of MRI sequences based on the performed spatially-resolved analysis; and storing the updated value of the at least one RF parameter.

(2) The method of (1), further including, but not limited to, wherein the at least one RF parameter is an RF transmitter gain level.

(3) The method of any one of (1) and (2), wherein the at least one RF parameter is an RF transmitter gain level.

(4) The method of any one of (1)-(3), wherein performing at least one spatially-resolved analysis on the spatially-resolved subset of the obtained spatially-resolved B1 amplitude measurements includes, but is not limited to, selecting the spatially-resolved subset using a histogram.

(5) The method of any one of (1)-(3), wherein performing at least one spatially-resolved analysis on the spatially-resolved subset of the obtained spatially-resolved B1 amplitude measurements includes, but is not limited to, selecting the spatially-resolved subset using a region of interest.

(6) The method of any one of (1)-(3), wherein the spatially-resolved subset is a lowest percentage of the obtained spatially-resolved B1 amplitude measurements, and wherein determining the updated value of the at least one RF parameter includes, but is not limited to, determining the updated value of the at least one RF parameter based on a ratio of (1) a target B1 amplitude value and (2) an average value of the lowest percentage of the obtained spatially-resolved B1 amplitude measurements.

(7) The method of any one of (1)-(3), wherein the spatially-resolved subset is (a) a lowest first percentage of the obtained spatially-resolved B1 amplitude measurements and (b) a highest second percentage of the obtained spatially-resolved B1 amplitude measurements, and wherein determining the updated value of the at least one RF parameter includes, but is not limited to, determining the updated value of the at least one RF parameter based on a ratio of (1) a target B1 amplitude value and (2) an average value of (2a) an average value of the lowest first percentage of the obtained spatially-resolved B1 amplitude measurements and (2b) an average value of the highest second percentage of the obtained spatially-resolved B1 amplitude measurements.

(8) The method of any one of (1)-(7), wherein obtaining the spatially-resolved B1 amplitude measurements includes, but is not limited to, using a Bloch-Siegert shift sequence to obtain the spatially-resolved B1 amplitude measurements.

(9) The method of any one of (1)-(7), wherein obtaining the spatially-resolved B1 amplitude measurements includes, but is not limited to, using Actual Flip Angle imaging to obtain the spatially-resolved B1 amplitude measurements.

(10) The method of any one of (1)-(9), wherein obtaining the spatially-resolved B1 amplitude measurements includes, but is not limited to, obtaining a 1D projection.

(11) The method of any one of (1)-(9), wherein obtaining the spatially-resolved B1 amplitude measurements includes, but is not limited to, obtaining a 2D slice.

(12) The method of any one of (1)-(9), wherein obtaining the spatially-resolved B1 amplitude measurements includes, but is not limited to, a 3D volume.

(13) The method of any one of (1)-(12), wherein performing the at least one spatially-resolved analysis on the spatially-resolved subset of the obtained spatially-resolved B1 amplitude measurements includes, but is not limited to: performing filtering on the spatially-resolved subset of the obtained spatially-resolved B1 amplitude measurements; and performing the at least one spatially-resolved analysis on the filtered spatially-resolved B1 amplitude measurements.

(14) The method of any one of (1), (2) and (4)-(13), wherein the at least one RF parameter is a flip angle.

(15) The method of any one of (1), (2) and (4)-(13), wherein the at least one RF parameter is a shim setting.

(16) A Magnetic Resonance Imaging (MRI) system including, but not limited to: a gantry; at least one RF transmitter coil; and an RF transmitter coil controller configured to perform the steps of any one of (1)-(15).

(17) A computer program product including, but not limited to, a computer readable storage medium configured to be communicatively coupled to a computer processor, wherein the computer readable storage medium includes computer instructions which, when executed by the computer processor, cause the computer processor to perform the steps of any one of (1)-(15).

While certain implementations have been described, these implementations have been presented by way of example only, and are not intended to limit the teachings of this disclosure. Indeed, the novel methods, apparatuses and systems described herein can be embodied in a variety of other forms; furthermore, various omissions, substitutions and changes in the form of the methods, apparatuses and systems described herein can be made without departing from the spirit of this disclosure.

1. An image processing method comprising:
obtaining spatially-resolved B1 amplitude measurements obtained using at least one RF parameter;
performing at least one spatially-resolved analysis on a spatially-resolved subset of the obtained spatially-resolved B1 amplitude measurements;
determining an updated value of the at least one RF parameter to be used in a series of MRI sequences based on the performed spatially-resolved analysis; and
storing the updated value of the at least one RF parameter.

2. The method according to claim 1, further comprising performing the series of MRI sequences with the updated value of the at least one RF parameter.

3. The method according to claim 1, wherein the at least one RF parameter is an RF transmitter gain level.

4. The method according to claim 1, wherein performing at least one spatially-resolved analysis on the spatially-resolved subset of the obtained spatially-resolved B1 amplitude measurements comprises selecting the spatially-resolved subset using a histogram.

5. The method according to claim 1, wherein performing at least one spatially-resolved analysis on the spatially-resolved subset of the obtained spatially-resolved B1 amplitude measurements comprises selecting the spatially-resolved subset using a region of interest.

6. The method according to claim 1, wherein the spatially-resolved subset is a lowest percentage of the obtained spatially-resolved B1 amplitude measurements, and wherein determining the updated value of the at least one RF parameter comprises determining the updated value of the at least one RF parameter based on a ratio of (1) a target B1 amplitude value and (2) an average value of the lowest percentage of the obtained spatially-resolved B1 amplitude measurements.

7. The method according to claim 1, wherein the spatially-resolved subset is (a) a lowest first percentage of the obtained spatially-resolved B1 amplitude measurements and (b) a highest second percentage of the obtained spatially-resolved B1 amplitude measurements, and wherein determining the updated value of the at least one RF parameter comprises determining the updated value of the at least one RF parameter based on a ratio of (1) a target B1 amplitude value and (2) an average value of (2a) an average value of the lowest first percentage of the obtained spatially-resolved B1 amplitude measurements and (2b) an average value of the highest second percentage of the obtained spatially-resolved B1 amplitude measurements.

8. The method according to claim 1, wherein obtaining the spatially-resolved B1 amplitude measurements comprises using a Bloch-Siegert shift sequence to obtain the spatially-resolved B1 amplitude measurements.

9. The method according to claim 1, wherein obtaining the spatially-resolved B1 amplitude measurements comprises using Actual Flip Angle imaging to obtain the spatially-resolved B1 amplitude measurements.

10. The method according to claim 1, wherein obtaining the spatially-resolved B1 amplitude measurements comprises obtaining a 1D projection.

11. The method according to claim 1, wherein obtaining the spatially-resolved B1 amplitude measurements comprises obtaining a 2D slice.

12. The method according to claim 1, wherein obtaining the spatially-resolved B1 amplitude measurements comprises obtaining a 3D volume.

13. The method according to claim 1, wherein performing the at least one spatially-resolved analysis on the spatially-resolved subset of the obtained spatially-resolved B1 amplitude measurements comprises:
performing filtering on the spatially-resolved subset of the obtained spatially-resolved B1 amplitude measurements; and
performing the at least one spatially-resolved analysis on the filtered spatially-resolved B1 amplitude measurements.

14. The method according to claim 1, wherein the at least one RF parameter is a flip angle.

15. The method according to claim 1, wherein the at least one RF parameter is a shim setting.

16. A Magnetic Resonance Imaging (MRI) system comprising:
a gantry;
at least one RF transmitter coil; and
an RF transmitter coil controller configured to:
obtain spatially-resolved B1 amplitude measurements obtained using at least one RF parameter;
perform at least one spatially-resolved analysis on a spatially-resolved subset of the obtained spatially-resolved B1 amplitude measurements;
determine an updated value of the at least one RF parameter to be used in a series of MRI sequences based on the performed spatially-resolved analysis; and
store the updated value of the at least one RF parameter.

17. A computer program product comprising:
a computer readable storage medium configured to be communicatively coupled to a computer processor, wherein the computer readable storage medium includes computer instructions which, when executed by the computer processor, cause the computer processor to perform the steps of:
obtaining spatially-resolved B1 amplitude measurements obtained using at least one RF parameter;
performing at least one spatially-resolved analysis on a spatially-resolved subset of the obtained spatially-resolved B1 amplitude measurements;
determining an updated value of the at least one RF parameter to be used in a series of MRI sequences based on the performed spatially-resolved analysis; and
storing the updated value of the at least one RF parameter.
